(19) United States
(12) Patent Application Publication
(10) Pub. No.: US 2007/0095567 A1
(43) Pub. Date: May 3, 2007

(54) EMI vent panels including electrically-conductive porous substrates and meshes

(76) Inventors: Amy L. Boyce, Saint Charles, MO (US); Kelly G. Cook, Saint Louis, MO (US); Larry Don Creasy JR., Saint Clair, MO (US); David B. Wood, Saint Louis, MO (US)

Correspondence Address: Anthony G. Fussner, Suite 400, 7700 Bonhomme, St. Louis, MO, 63105, US

(21) Appl. No.: 11/590,523

(22) Filed: Oct. 31, 2006

Related U.S. Application Data
(60) Provisional application No. 60/732,022, filed on Nov. 1, 2005.

(51) Int. Cl. H05K 9/00

(52) U.S. Cl. 174/383

(57) ABSTRACT

An electromagnetic interference (EMI) shielding vent panel according to one embodiment generally includes an electrically-conductive porous substrate. The electrically-conductive porous substrate may include electrically-conductive reticulated or open-celled polymeric foam having a plurality of pores in a substantially nonuniform configuration. The vent panel may also include electrically-conductive wire mesh adjacent at least a portion of the electrically-conductive porous substrate for increasing shielding effectiveness.

This application claims the benefit of U.S. Provisional Patent Application No. 60/732,022 filed Nov. 1, 2005, the disclosure of which is incorporated herein by reference.

### FIELD

The present disclosure relates to electromagnetic interference (EMI) shielding vent panels that include electrically-conductive porous substrates and meshes.

### BACKGROUND

The statements in this background section merely provide background information related to the present disclosure and may not constitute prior art.

The operation of electronic devices generates electromagnetic radiation within the electronic circuitry of the equipment. Such radiation results in electromagnetic interference (EMI), which can interfere with the operation of other electronic devices within a certain proximity. A common solution to ameliorate the effects of EMI has been the development of shields capable of absorbing and/or reflecting EMI energy.

### SUMMARY

According to various aspects, the disclosure provides EMI vent panels and shields. In one exemplary embodiment, an EMI vent panel generally includes an electrically-conductive porous substrate. The EMI vent panel may also include electrically-conductive wire mesh adjacent at least a portion of the electrically-conductive porous substrate for increasing shielding effectiveness.

Further aspects and features of the present disclosure will become apparent from the detailed description provided hereinafter. In addition, any one or more aspects of the disclosure may be implemented individually or in any combination with any one or more of the other aspects of the disclosure. It should be understood that the detailed description and specific examples, while indicating exemplary embodiments of the disclosure, are intended for purposes of illustration only and are not intended to limit the scope of the disclosure.

### DRAWINGS

The drawings described herein are for illustration purposes only and are not intended to limit the scope of the present disclosure in any way.

FIG. 1 is an exploded perspective view of an EMI vent panel including an electrically-conductive foam substrate and an electrically-conductive wire mesh according to one exemplary embodiment;

FIG. 2 is a flowchart illustrating an exemplary method for forming an EMI vent panel according to exemplary embodiments;

FIG. 3 is an exploded perspective view of an EMI vent panel including an electrically-conductive foam substrate and electrically-conductive wire mesh provided on both sides of the electrically-conductive foam according to another embodiment;

FIGS. 4A and 4B are tables summarizing data collected for various exemplary embodiments of EMI vent panels that were tested for shielding effectiveness;

FIGS. 5A and 5B are exemplary line graphs created from the data in FIGS. 4A and 4B, respectively, showing shielding effectiveness versus frequency for various exemplary embodiments of EMI vent panels;

FIGS. 6A through 6C are tables summarizing data collected for various exemplary embodiments of EMI vent panels that were tested per ASTM F778 (Clear Air Permeability, 2001);

FIGS. 7A through 7C are exemplary line graphs created from the data in FIGS. 6A through 6C, respectively, showing face velocity (in feet per minute) versus pressure drop (in inches of H₂O) for various exemplary embodiments of EMI vent panels;

FIGS. 8A through 8I are exemplary line graphs of flexure force showing displacement versus the force required for causing that displacement for various exemplary embodiments of EMI vent panels; and

FIG. 9 is a matrix listing components and attributes thereof for various exemplary embodiments of EMI vent panels along with exemplary test results relating to shielding effectiveness, airflow, and rigidity.

### DETAILED DESCRIPTION

The following description is merely exemplary in nature and is in no way intended to limit the present disclosure, application, or uses.

According to various aspects, the disclosure provides vent panels and/or air filtration panels that include electrically-conductive porous substrates (e.g., metallized porous substrate, open-celled polymeric foam rendered electrically-conductive by metallizing or plating, reticulated foams, etc.) and electrically-conductive meshes (e.g., metallic wire screens, metallic wire meshes, non-metallic wire meshes rendered electrically-conductive by metallizing or plating, etc.). The electrically-conductive mesh may be configured to increase shielding effectiveness and/or to reinforce the electrically-conductive porous substrate. In addition, the combined electrically-conductive porous substrate and mesh can be used, for example, for EMI shields, vent panels, air filtration panels, and/or thermal cooling.

Other aspects of the disclosure relate to methods of making and/or using vent panels, air filtration panels, and/or EMI shields. Further aspects and features of the present disclosure will become apparent from the detailed description and drawings provided herein. In addition, any one or more aspects of the disclosure may be implemented individually or in any combination with any one or more of the other aspects of the disclosure.

Referring now to FIG. 1, there is shown an exemplary embodiment of a vent panel 100 embodying several aspects of the disclosure. As shown, the vent panel 100 generally includes an electrically-conductive porous substrate 104 and electrically-conductive mesh 108.

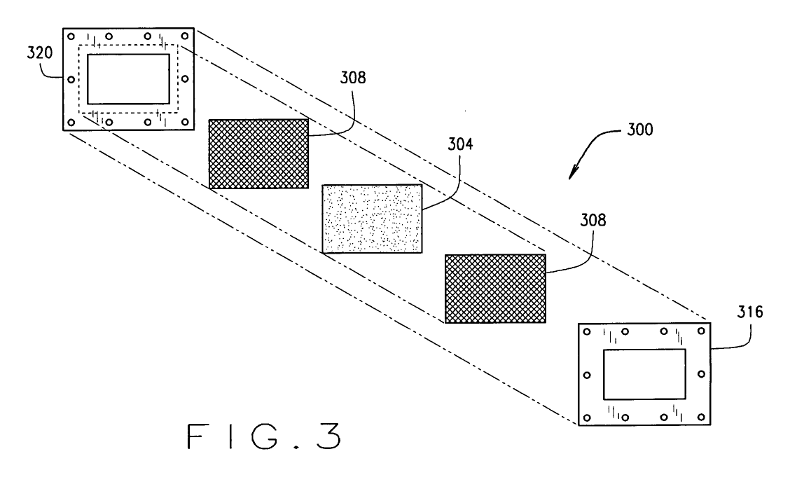

In the particular example of FIG. 1, the electrically-conductive mesh 108 is provided along only one side of the electrically-conductive porous substrate 104. Alternatively, electrically-conductive mesh may also be provided on the other side of the electrically-conductive porous substrate. For example, FIG. 3 illustrates another exemplary embodiment of a vent panel 300 with electrically-conductive mesh 308 on both sides of an electrically-conductive porous substrate 304. Each electrically-conductive mesh 308 may comprise the same material as the other mesh, or they may be formed from different materials.

With continued reference to FIG. 1, the substrate 104 and mesh 108 can be engaged by way of a frame. In this particular embodiment, the frame includes two pieces 116 and 120 configured to be fastened to one another generally about the respective perimeter edge portions of the substrate 104 and mesh 108. The frame pieces 116 and 120 include corresponding fastener holes for receiving fasteners, such as screws, rivets, combinations thereof, among other suitable mechanical fasteners. Likewise, the substrate 304 and meshes 308 shown in FIG. 3 can also be engaged by way of frame pieces 316 and 320. In addition to, or as an alterative to frame pieces 116, 120, 316, 320, other embodiments may include electrically-conductive porous substrates and meshes engaged with one another by using other suitable means and processes, such as adhesives (e.g., electrically-conductive adhesives, etc.), flame lamination, soldering, welding, crimping, mechanical fasteners, combinations thereof, etc.

In various embodiments, the electrically-conductive porous substrate may include at least some pores or cells (and, in some embodiments, all pores and cells) in a substantially nonuniform configuration, such as a non-honeycombed configuration, etc. For example, the pores or cells may be variously or irregularly-shaped, variously spaced, and/or have varying sizes. The pores or cells may, for example, be interconnected in various manners with other pores or cells to allow fluid flow through the electrically-conductive porous substrate. By eliminating (or at least reducing) the need for more costly uniform structures (e.g., honeycombed structures), various embodiments disclosed herein provide relatively low cost, lightweight options for EMI shielding vent panels and air filtration panels. Alternative embodiments may include electrically-conductive porous substrates having pores or cells in a uniform configuration or in an at least partially uniform configuration. In such alternative embodiments, one or more (and, in some embodiments, all) of the pores or cells may have a honeycomb structure.

In addition, the cell structure of the porous substrate may be fully open or partially open depending, for example, on the particular application. Various techniques can be used to provide an open or partially open cell structure. By way of example only, foam can be quenched via contact with a caustic solution. Additionally or alternatively, the foam can be treated with an electric charge, such as by subjecting the foam to a zapping process. In various embodiments, quenched polymeric foam is used as the starting material for the porous substrate (which may, for example, then be metallized as described hereinafter).

In addition, the particular pore per inch rating for the porous substrate may depend, for example, on the particular application intended for the device. For example, a material having a higher pore per inch rating generally provides for better EMI shielding, while a lower pore per inch rating generally provides for better air circulation and air flow through the material.

In various embodiments, the porous substrate includes a pore per inch rating less than about fifty pores per inch. In another embodiment, the porous substrate has a pore density between about four pores per inch to about twenty pores per inch. In a further embodiment, the porous substrate has a pore density of about four pores per inch. Alternatively, any other suitable pore size can be used depending, for example, on the intended end use. By way of example, a suitable pore size may be from about four pores per inch to about twenty pores per inch for ventilation/air filtration product applications. For EMI gasket applications, however, a suitable pore size may be from about thirty pores per inch to about eighty pores per inch.

The dimensions of the porous substrate may be varied depending on the particular installation, space considerations, etc. By way of example only, one exemplary embodiment includes a porous substrate having a thickness of about 1/32 inch to about two inches, a width of about ¼ inch to about sixty inches, and a length of about ¼ inch to about one thousand feet. The dimensions set forth in this paragraph (as are all dimensions herein) are mere examples and can be varied as understood by those skilled in the art.

The porous substrate may be arranged into various shapes depending on the particular application. The porous substrate may be shaped using various techniques including, for example, extrusion, molding, cutting, etc. In addition, the porous substrate may be attached to an additional substrate, for example, to provide additional support, stiffness, and/or shape. This additional substrate may be attached to a surface using various methods, thereby facilitating the mounting and/or installation of the porous substrate and mesh engaged therewith.

The porous substrate may also be flame retardant. For example, the porous substrate may be made from one or more flame retardant materials. Additionally or alternatively, the porous substrate may be treated to increase its flame retardant characteristics thereof using various techniques including, for example, treating the porous substrate with flame retardant. Exemplary flame retardant materials include, for example, halogen compounds, hydroxides, graphite, halogen-free flame retardants, combinations thereof, etc. Typical halogen compounds include, for example, chlorinated and brominated compounds. Exemplary metal hydroxides include aluminum hydroxide and magnesium hydroxide. The porous substrate can be treated before and/or after metallizing the porous substrate. By way of example only, the porous substrate may be provided with flame retardant properties and/or be rendered flame retardant by one or more of the processes described in U.S. Pat. No. 7,060,348 entitled “Flame Retardant, Electrically Conductive Shielding Materials and Methods of Making the Same” and/or pending U.S. patent application No. 11/389,301, filed Mar. 24, 2006 entitled “Flame Retardant, Electrically Conductive Shielding Materials and Methods of Making the Same.” The disclosures of which are incorporated herein by reference. In such example embodiments, a porous material may be impregnated with an effective amount of flame retardant that provides the impregnated shielding material with at least horizontal flame rating (e.g., V0, V1, V2, HB, HF-1 per Underwriter's Laboratories (UL) No. 94, “Tests for Flammability of Plastic Materials for Parts in Devices and Appliances” (1996)) without compromising the shielding properties necessary for meeting EMI shielding requirements, such as retaining z-axis conductivity or bulk resistivity sufficient for EMI shielding applications. In addition, the flame retardant may be dispersed such that the impregnated shielding material is substantially free of occluded interstices, for example, with less than a majority of the interstices (or pores) of the porous material provided with the flame retardant are occluded or blocked. In other embodiments, less than about 25 percent of the interstices (or pores) may occluded, and with further embodiments having less than about 10 percent of the interstices being occluded.

In various embodiments, the porous substrate is rendered electrically conductive by metallizing the porous substrate. In one particular embodiment, the porous substrate is made electrically conductive by applying one or more metallic layers over at least one surface portion of the porous substrate, and, in some embodiments, the entire surface of the porous substrate.

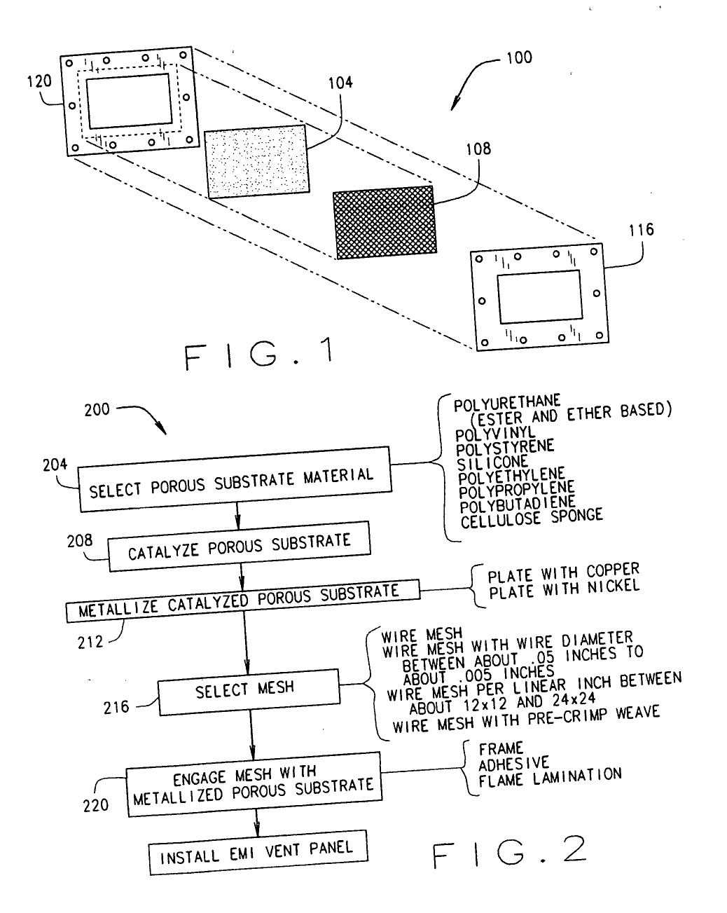

By way of example only, the porous substrate may be metallized in accordance with the operations or processes 208 and 212 of the exemplary process 200 shown in FIG. 2. After selecting a suitable material for the porous substrate at operation 204, the porous substrate is catalyzed at operation 208. By way of example only, various embodiments may catalyze the porous substrate at operation 208 by using one or more of the processes or methods described in U.S. Pat. 6,395,402 entitled “Electrically Conductive Polymeric Foam and Method of Preparation Thereof”, the disclosure of which is incorporated herein by reference.

With continued reference to FIG. 2, operation 212 includes plating the catalyzed porous substrate with one or more metals. Exemplary materials that can be used at operation 212 include copper, nickel, nickel copper, palladium, platinum, silver, tin, tin copper, gold, alloys thereof, etc. In one particular embodiment, the catalyzed porous substrate is plated with copper, and then plated with nickel layer. Alternatively, the porous substrate may be provided with more or less than two metal layers, can be provided with metals using other processes (e.g., batch plating, reel-to-reel metal plating, physical vapor deposition, electroless plating, electrolytic plating, combinations thereof, etc.), and/or be provided with metals besides nickel and copper depending, for example, on the particular application intended for the end product.

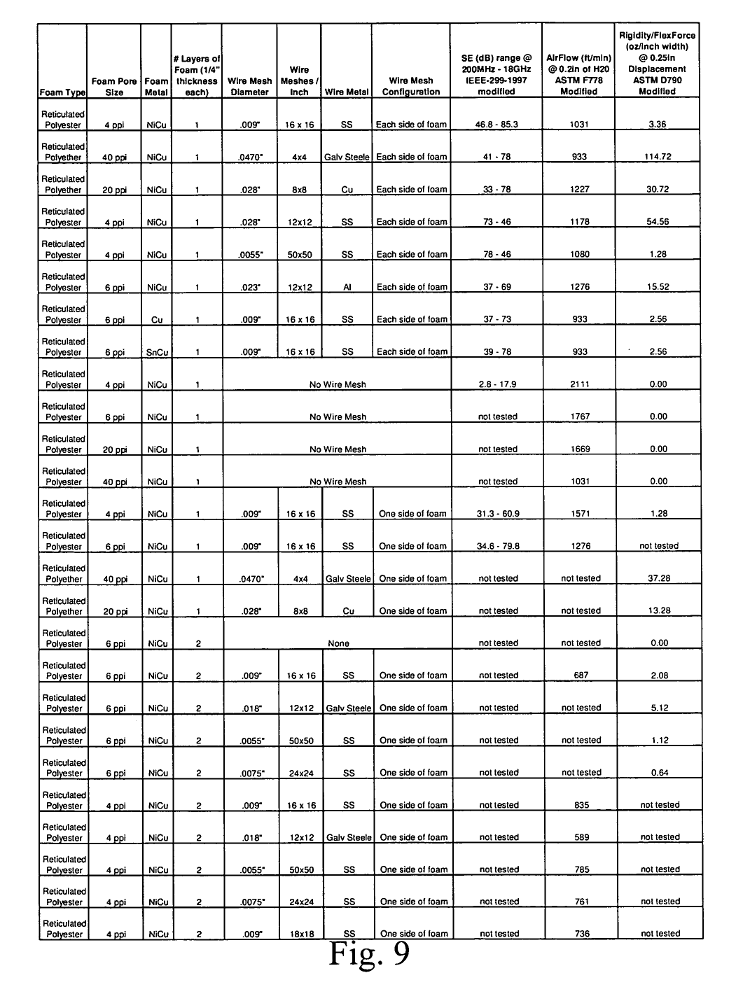

A wide range of materials may be used for the porous substrate. Exemplary materials (some of which are shown at operation 204 in FIG. 2 and in FIG. 9) include ester-based polyurethane (e.g., reticulated polyester having four or six pores per inch, etc.), ether-based polyurethane (e.g., reticulated polyether having twenty, thirty or forty pores per inch, etc.), polyvinyl, polystyrene, silicone, polyethylene, polypropylene, polybutadiene, cellulose sponge, combinations thereof, among other suitable materials. Alternative embodiments include porous substrates formed from electrically-conductive materials (e.g., woven wire mesh, sintered porous metals, metal wool or sponge, combinations thereof, etc.), thereby eliminating (or at least reducing) the need for metallizing the already electrically-conductive porous substrate.

In various embodiments, the porous substrate may include polymeric foam. Generally, polymeric materials are not electrically conductive, and they generally cannot be plated by traditional electrolytic or electroless processes. To apply a plated metallic layer to the polymeric foam which adheres thereto without peeling, various embodiments may include subjecting the foam surface to a pretreatment process, which is then followed by electroless plating. By way of example only, various embodiments may include metallizing or providing a polymeric foam with one or more metal layers by one or more of the processes described in U.S. Pat. No. 6,395,402, the disclosure of which is incorporated herein by reference.

As shown in FIG. 1, the vent panel 100 may also include one or more pieces or layers of electrically-conductive mesh 108. In various embodiments, the mesh may be engaged with the electrically-conductive porous substrate so as to reinforce the electrically-conductive porous substrate. With reinforcement provided by the mesh, various embodiments can include porous substrates with substantially nonuniform pores or cells (which tend to be lighter, less costly to manufacture, and less rigid than honeycombed panels) and still have sufficient strength (and in some embodiments, comparable or exceeding that of honeycombed vent panels) suitable for EMI shielding and non-EMI shielding applications. In addition, the combination of foam and mesh configurations in various embodiments of the disclosure allow the user to balance EMI, airflow, and air filtration for various application requirements with sufficient strength/rigidity at a relatively low cost, aesthetically pleasing, and better shielding effectiveness than that which is usually possible with metallized foam or mesh alone. To this end, a user may, for example, select from amongst the various combinations of foams and meshes shown in FIG. 9, where that selection is based, at least in part, on the combination's ability to attain acceptable results in each of the following categories: shielding effectiveness, airflow, and rigidity.

The preferred combination and/or preferred mesh configuration (e.g., material, shape, size, meshes per linear foot, etc.) may vary depending, for example, on the particular end use for the product. Some exemplary configurations that may be selected for the mesh are shown by way of example at operation 216 in FIG. 2 and in the matrix in FIG. 9. In addition, the table immediately below also provides exemplary wire mesh configurations which may be used along one or both sides (or side portion thereof) of an electrically-conductive porous substrate.

| Wire Mesh Diameter | Wire Meshes/Inch | Wire Metal |
|---|---|---|
| .009″ | 16 × 16 | Stainless Steel |
| .023″ | 12 × 12 | Aluminum |
| .023″ | 12 × 12 | Copper |
| .028″ | 8 × 8 | Copper |
| .009″ | 18 × 18 | Stainless Steel |
| .009″ | 16 × 16 | Copper |
| .028″ | 8 × 8 | Stainless Steel |
| .0055″ | 50 × 50 | Stainless Steel |
| .0470″ | 4 × 4 | Galvanized Steel |
| .0180″ | 12 × 12 | Galvanized Steel |
| .0075″ | 24 × 24 | Stainless Steel |
| .0140″ | 24 × 24 | Galvanized Steel |
| .0037″ | 120 × 120 | Aluminum |

With further reference to FIG. 2, one particular embodiment includes the electrically-conductive mesh with a wire diameter of between about 0.005 inches and about 0.05 inches. In another embodiment, the electrically-conductive mesh has a wire diameter of about 0.009 inches. The dimensions set forth in this paragraph (as are all dimensions herein) are mere examples and may be varied as understood by those skilled in the art.

In various embodiments, the electrically-conductive mesh can have between about twelve by twelve meshes per linear inch and about twenty-four by twenty-four meshes per linear inch. In one particular embodiment, the electrically-conductive mesh has about sixteen by sixteen meshes per linear inch. In another embodiment, the electrically-conductive mesh has about twelve by twelve meshes per linear inch. In a further embodiment, the electrically-conductive mesh has about twenty-four by twenty-four meshes per linear inch.

The electrically-conductive mesh may be formed from a wide range of materials, including electrically-conductive materials and non-conductive materials rendered electrically conductive, for example, by metallizing. By way of example only, various embodiments include a metallic wire mesh formed from an electrically-conductive material, such as copper, nickel, aluminum, stainless steel, alloys thereof, etc. Alternative embodiments include a metallized wire mesh formed from a non-conductive or dielectric material that is metallized (or otherwise treated, etc.) to render the otherwise non-conductive material electrically conductive. By way of example only, one embodiment includes a metallized wire mesh formed from glued, woven, or knitted polymeric yarn (such as nylon, polyester, and the like) or extruded polymeric mesh that has been metallized with copper, nickel, palladium, platinum, silver, tin, gold, an alloy thereof, etc. In various embodiments, the electrically-conductive mesh may also be formed of various types of weaves and knits known by those skilled in the art.

By way of example only, one particular embodiment includes metallized foam having six pores per inch and one layer of metal wire mesh having a 0.009 inch wire diameter and 16×16 meshes per linear inch. A test specimen in accordance with this particular embodiment exhibited a shielding effectiveness of greater than about sixty-five decibels over a frequency range from about two hundred megahertz to about two gigahertz using test method IEEE-299-1997 specification modified by utilizing a MIL-DTL-83528C test fixture (modified to fit the sample size) (MIL-DTL-83528C Detail Specification Gasketing Material, Conductive, Shielding Gasket, Electronic, Elastomer, EMI/RFI General Specification For. 5 Jan., 2001). This test specimen also exhibited an airflow of about 6.1 cubic feet per minute per square inch (CFM/Sq In) at a pressure drop of about 0.2 inches of H₂O (per ASTM D 3574 Standard Test Methods For Flexible Cellular Materials—Slab, Bonded, and Molded Urethane Foams. Sep. 6, 2005).

As shown at operation 220 in FIG. 2, a wide range of methods and devices can be used to engage the electrically-conduct mesh and the porous substrate. In the exemplary embodiments shown in FIG. 1, frame pieces 116 and 120 are positioned generally about respective perimeter edge portions of the substrate 104 and the mesh 108. The frame pieces 116 and 120 are fastened to one another using mechanical fasteners inserted into the corresponding fastener holes. A wide range of mechanical fasteners can be used including screws, rivets, combinations thereof, among other suitable mechanical fasteners. In addition to, or as an alterative to the frame pieces, other embodiments include an electrically-conductive porous substrate engaged with an electrically-conductive mesh by using other suitable means and processes, such as adhesives (e.g., electrically-conductive adhesives, etc.), flame lamination, soldering, welding, crimping, mechanical fasteners, combinations thereof, etc. Furthermore, other embodiments may include one-piece frames that go around both the top and bottom of the foam/wire mesh, or frames on only one side of the foam/wire mesh with foam/wire mesh being attached in some suitable manner, such as adhesives, etc.

In order to further illustrate various aspects of the present disclosure and possible advantages thereof, the following non-limiting examples and test results are given. These test specimens and exemplary test results are set forth for purposes of illustration only, and not for purposes of limitation.

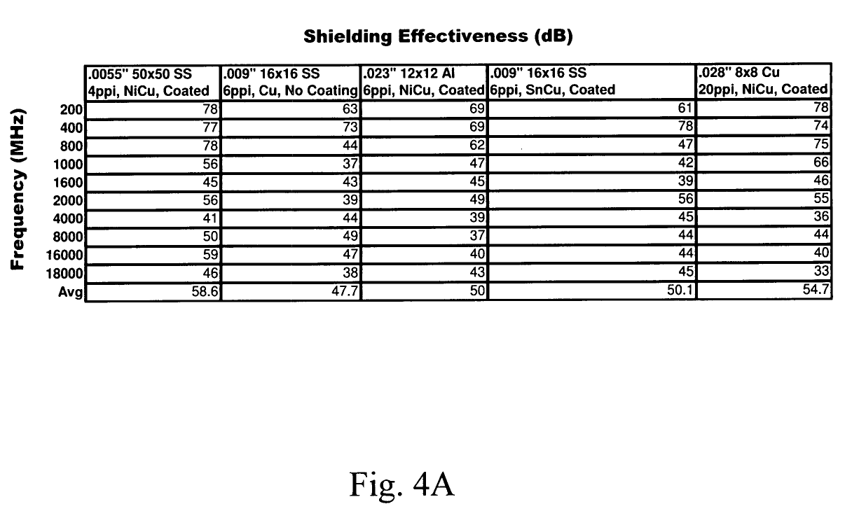

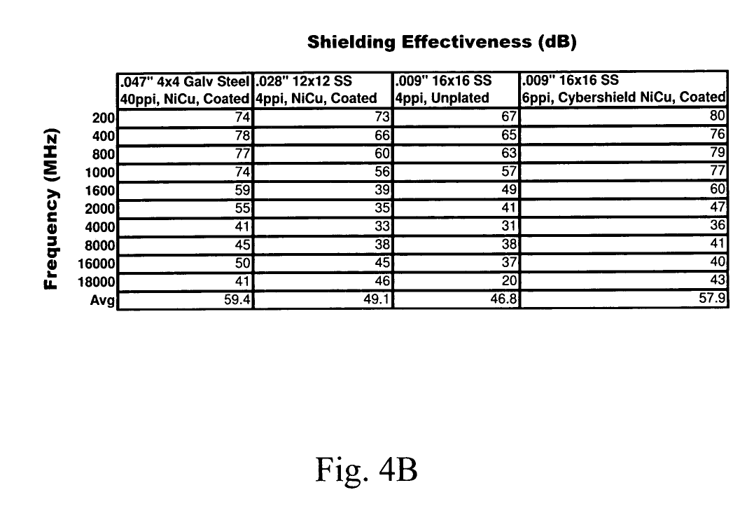

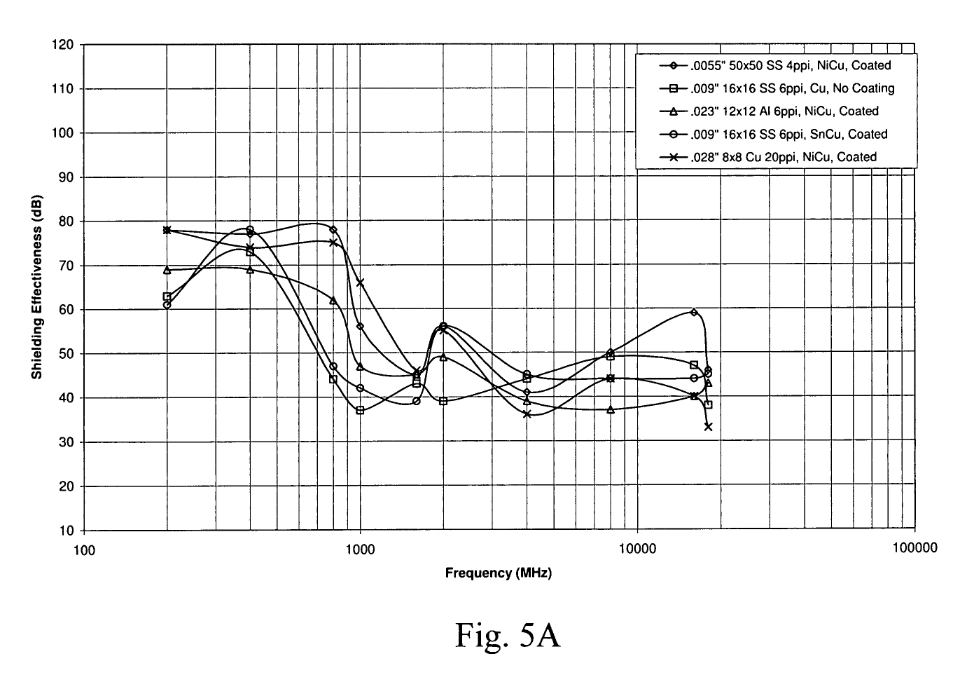

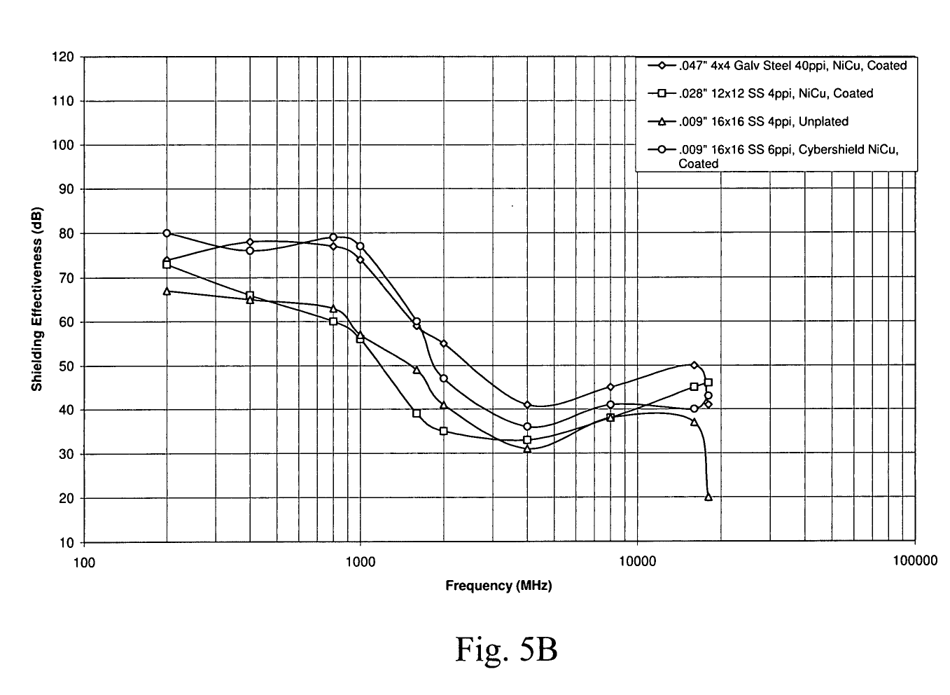

FIGS. 4A and 4B are tables summarizing data collected for nine different embodiments of EMI vent panels that were tested for shielding effectiveness using test method IEEE-299-1997 specification modified by utilizing a MIL-DTL-83528C test fixture, which was modified to fit the sample size. FIGS. 5A and 5B are exemplary line graphs created from the data in FIGS. 4A and 4B, respectively, and showing electromagnetic shielding effectiveness characteristics over a frequency range from 200 MHz to 18 GHz. The following is a description of the test specimens in the order that they are provided in FIGS. 4A and 4B:
nickel copper plated 4 ppi reticulated polyester foam, type 304 stainless steel wire mesh with 0.055″ diameter wire and 50×50 mesh per inch pattern on each side of the foam, and urethane coating;
copper plated 6 ppi reticulated polyester foam and type 304 stainless steel wire mesh with 0.009″ diameter wire and 16×16 mesh per inch pattern on each side of the foam;
nickel copper plated 6 ppi reticulated polyester foam, aluminum wire mesh with 0.023″ diameter wire and 12×12 mesh per inch pattern on each side of the foam, and urethane coating;
tin copper plated 6 ppi reticulated polyester foam, type 304 stainless steel wire mesh with 0.009″ diameter wire and 16×16 mesh per inch pattern on each side of the foam, and urethane coating;
nickel copper plated 20 ppi reticulated polyether foam, copper wire mesh with 0.028″ diameter wire and 8×8 mesh per inch pattern on each side of the foam, and urethane coating;
nickel copper plated 40 ppi reticulated polyether foam, galvanized steel wire mesh with 0.047″ diameter wire and 4×4 mesh per inch pattern on each side of the foam, and urethane coating;
nickel copper plated 4 ppi reticulated polyester foam, type 304 stainless steel wire mesh with 0.028″ diameter wire and 12×12 mesh per inch pattern on each side of the foam, and urethane coating;
unplated 4 ppi reticulated polyester foam and type 304 stainless steel wire mesh with 0.009″ diameter wire and 16×16 mesh per inch pattern on each side of the foam; and
nickel copper plated 6 ppi reticulated polyester foam, type 304 stainless steel wire mesh with 0.009″ diameter wire and 16×16 mesh per inch pattern on each side of the foam, and urethane coating.

A description will now be provided of additional test specimens and exemplary test results in an effort to further illustrate the manner in which shielding effectiveness of an EMI vent panel may be improved by the addition of wire mesh with foam, as compared to the shielding effectiveness of the foam alone. For this particular series of testing, two different test specimens were created and tested. The first test specimen included ¼″ thick nickel copper plated 4 ppi eticulated polyester foam, which was cut to a 12″×12″ sample size. The second test specimen comprised the same ¼″ thick nickel copper plated 4 ppi reticulated polyester foam, along with type 304 stainless steel wire mesh on the opposing sides of the foam. The wire mesh was made of 0.009″ diameter wire and in a 16×16 mesh per inch pattern. Both test specimens were tested for shielding effectiveness using test method IEEE-299-1997 specification modified by utilizing a MIL-DTL-83528C test fixture, which was modified to fit the sample size. For the first test specimen without any wire mesh, the average attenuation was 11.3 dB across a frequency range of 200 MHz to 18 GHz. In comparison, the second test specimen had an average attenuation of 70.4 dB across a frequency range of 200 MHz to 18 GHz. Accordingly, this particular series of testing revealed a considerable improvement (from 11.3 db to 70.4 db) in the average attenuation across a frequency range of 200 MHz to 18 GHz, which may be attributable to the wire mesh. The exemplary shielding effectiveness test results set forth above are for purposes of illustration only, and not for purposes of limitation.

By way of further example, a third test specimen included ¼″ thick nickel copper plated 6 ppi reticulated polyester foam and stainless steel wire mesh along only one side of the foam. The wire mesh was made of 0.009″ diameter wire and provided in a 16×16 mesh per inch pattern. This third test specimen was also cut to a 12″×12″ sample size and then tested for shielding effectiveness using test method IEEE-299-1997 specification modified by utilizing a MIL-DTL-83528C test fixture, which was modified to fit the sample size. This third test specimen attained a shielding effectiveness of 66.5 dB at 2 GHz.

Additional test data relating to shielding effectiveness for various embodiments is also provided in FIG. 9. Again, this test data is provided for purposes of illustration only.

Regarding rigidity improvement, a description will now be provided of exemplary test results relating to the manner in which rigidity of an EMI vent panel may be improved by the addition of wire mesh with foam, as compared to the rigidity of the foam alone. For this testing, two different specimens were created and tested. The first test specimen included ¼″ thick nickel copper plated 4 ppi reticulated polyester foam, which was cut to a 1″×5″ sample size. The second test specimen included the same ¼″ thick nickel copper plated 4 ppi reticulated polyester foam, along with type 304 stainless steel wire mesh provided on both sides of the foam. The wire mesh was made of 0.009″ diameter wire and in a 16×16 mesh per inch pattern. Both specimens were tested for rigidity using a modified ASTM D790 standard, during which each specimen was tested to record the force required to displace that specimen at specified displacements over a finite range across a span of 2.28 inches and depth of 0.894 inches. For the first specimen without any wire mesh, the force required for displacement from 0.00 to 0.65 inches was below the detection capability of the load cell of the testing apparatus. In comparison, the second specimen having the wire mesh required a force of 4.8 oz/inch width for displacement up to 0.65 inches.

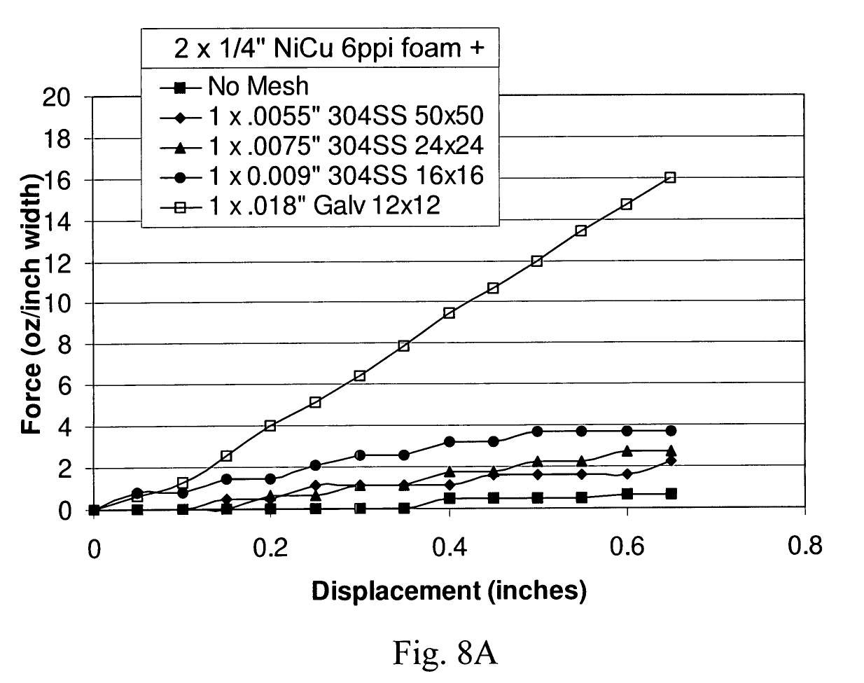

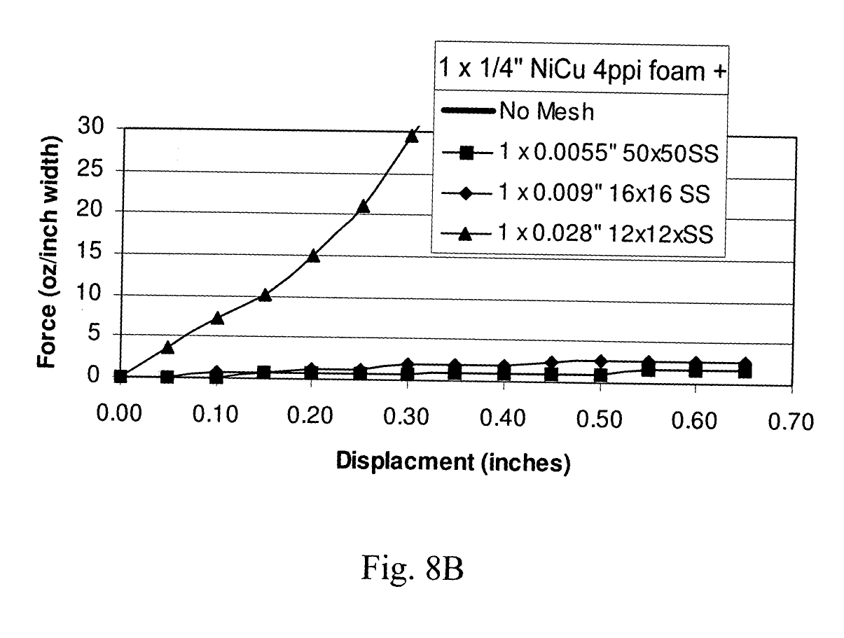

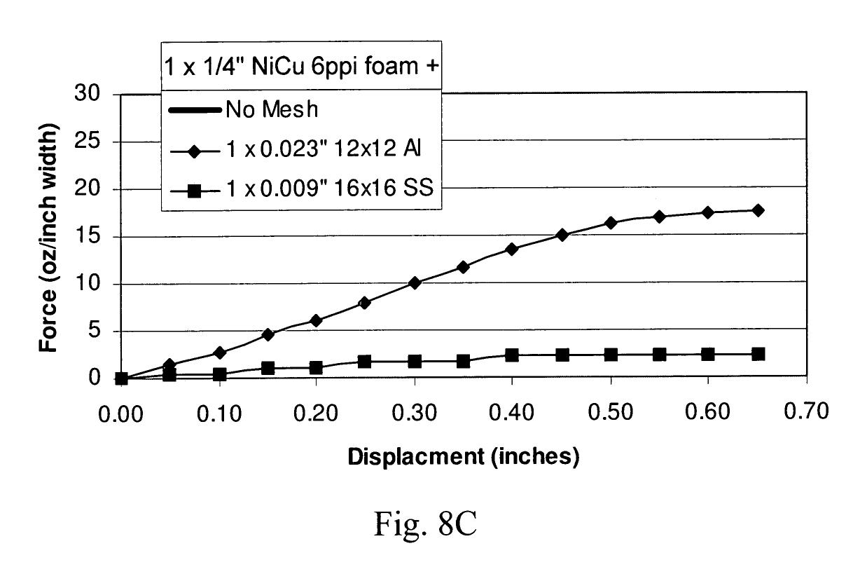

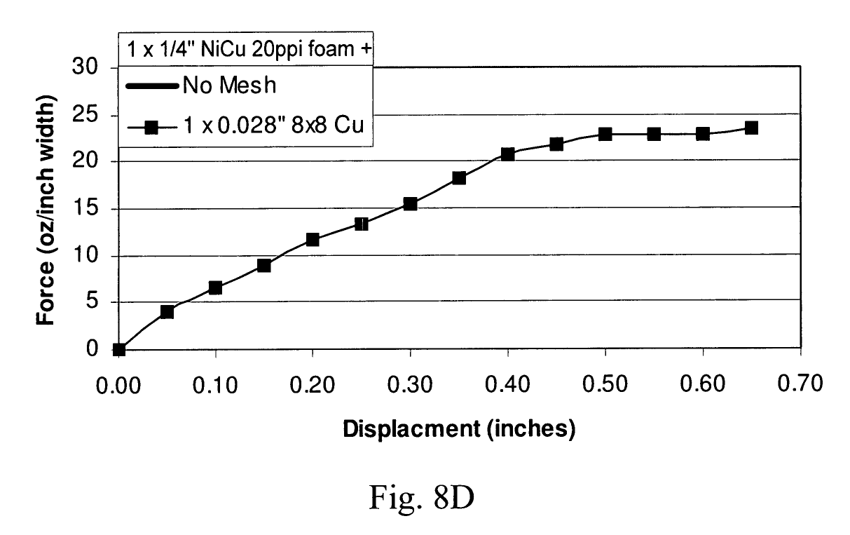

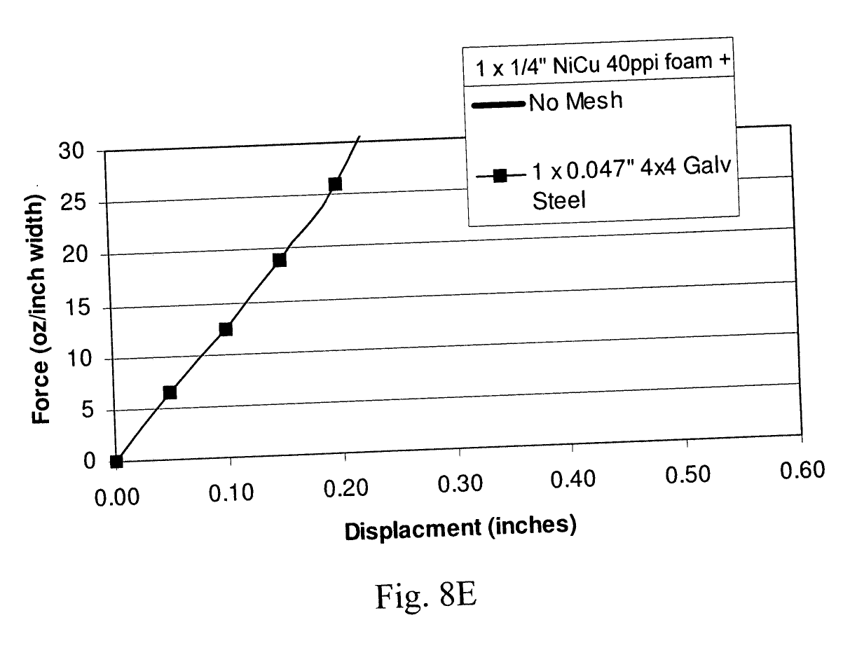

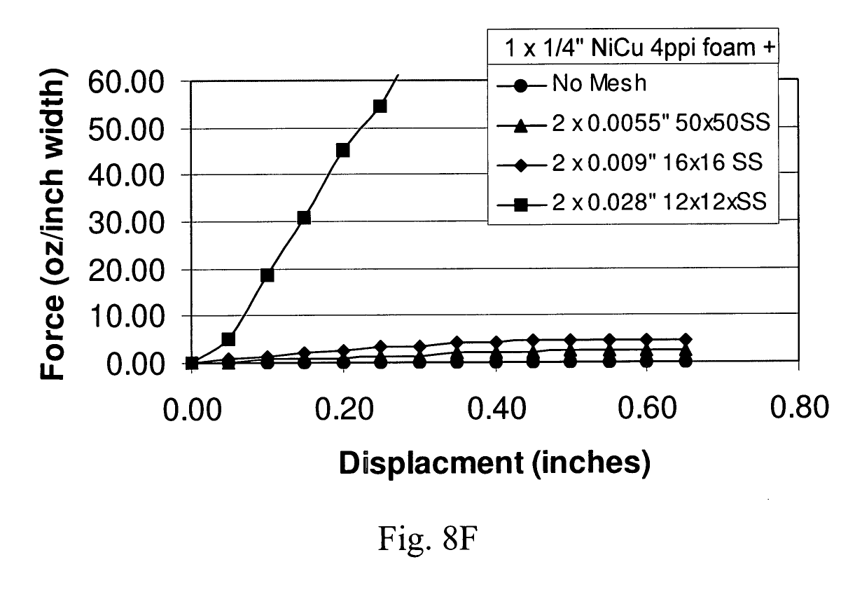

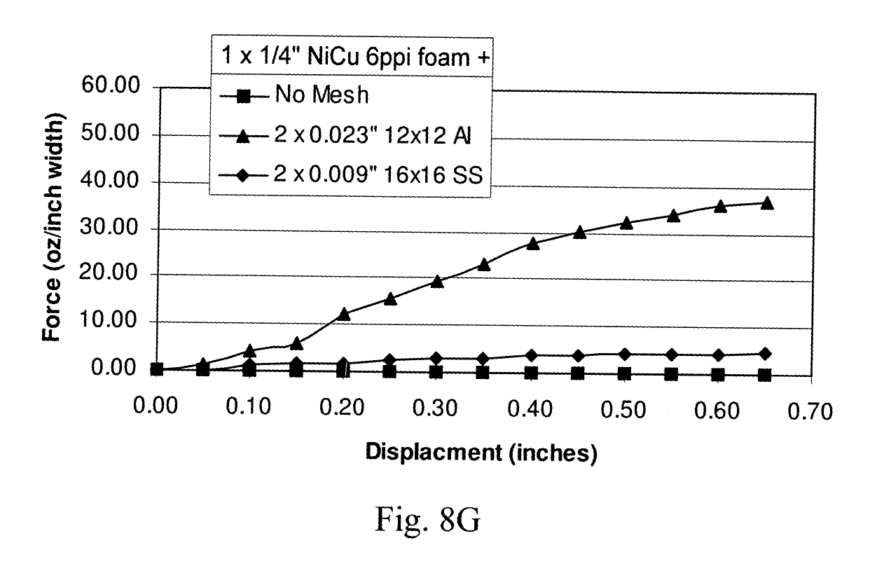

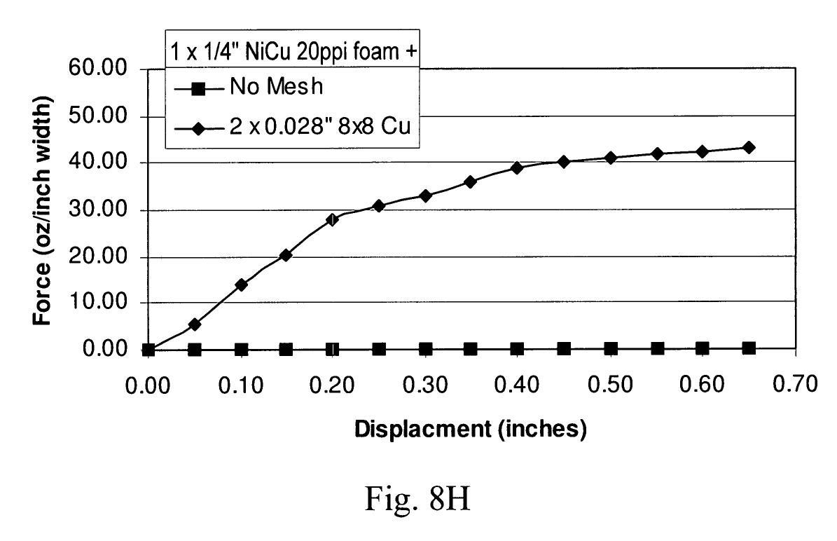

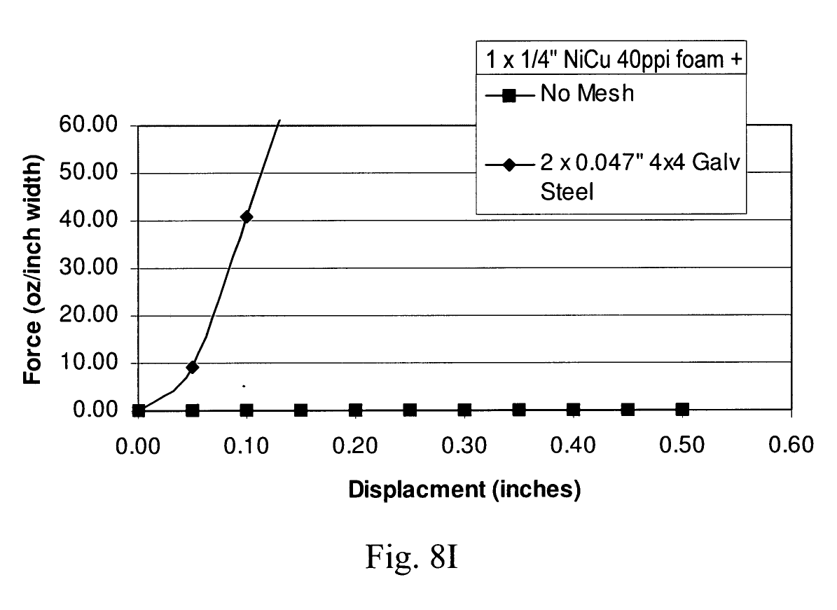

Additional test data relating to rigidity for various embodiments is also provided in FIGS. 8A through 8I, and FIG. 9. As before, this test data is provided for purposes of illustration only.

In regard to airflow, a description will now be provided of exemplary test results relating to the effect that the addition of wire mesh with foam has on airflow (as compared to the foam alone). For this particular testing, two specimens were created and tested. The first test specimen included ¼″ thick nickel copper plated 6 ppi reticulated polyester. The second test specimen comprised the same ¼″ thick nickel copper plated 6 ppi reticulated polyester, along with type 304 stainless steel wire mesh provided on both sides of the foam. The wire mesh was made of 0.009″ diameter wire and in a 16×16 mesh per inch pattern. Both specimens were tested per ASTM F778 with a modified sample size diameter of 47 mm. The first test specimen (without any wire mesh) attained airflow of 1767 feet/minute at 0.200 inches of H₂O pressure drop. In comparison, the second test specimen attained an air flow of 933 feet/minute at 0.200 inches of H₂O pressure drop tested. Accordingly, even with the addition of wire mesh, the second test specimen still achieved an airflow greater than 800 feet/minute at 0.200 inches of H₂O pressure drop, which may be considered to be the minimum desired airflow for EMI vent panels for some applications or installations. But the minimum desired airflow may also vary depending, for example, on the particular application or installation in which the EMI vent panel will be used and airflow needed or preferred for that application or installation.

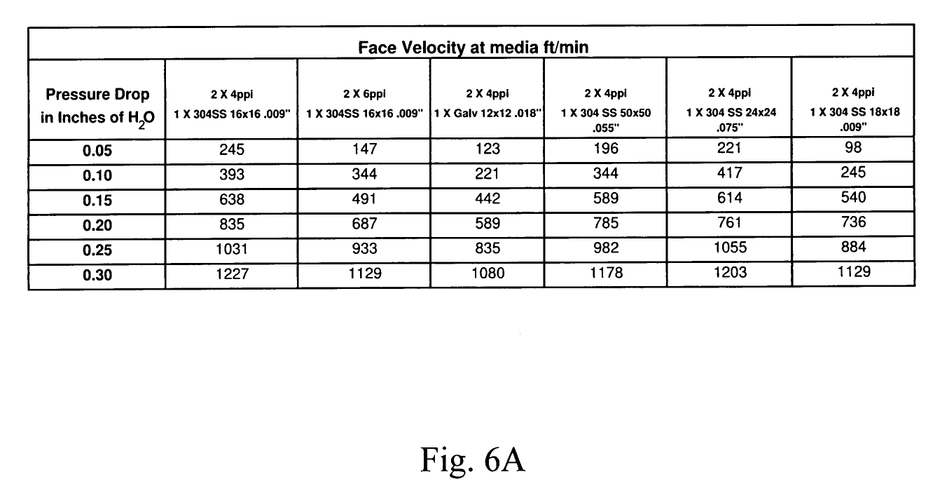

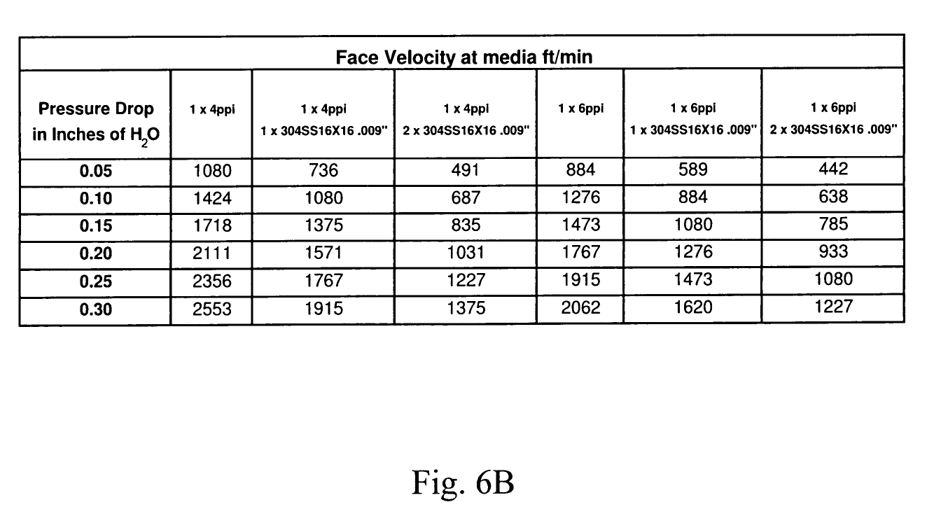

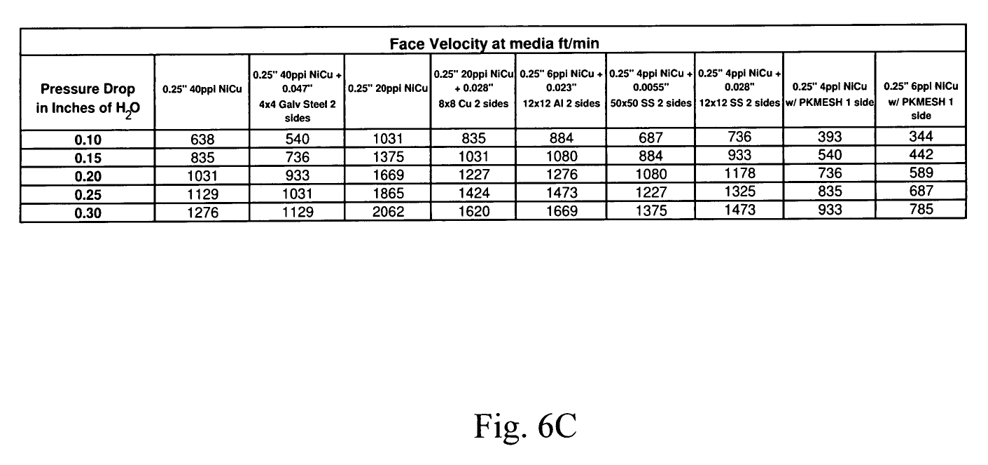

Additional test data relating to airflow associated with various embodiments is provided in FIGS. 6, 7, and FIG. 9. Again, this data is provided for purposes of illustration only.

Descriptions will now be provided of four additional exemplary embodiments of EMI vent panels that were tested for shielding effectiveness, airflow, and rigidity. As before, the specimens and exemplary test results are provided for purposes of illustration and clarification only, and not for purposes of limitation.

In a first of these additional embodiments, the test specimen included ¼″ thick nickel copper plated 40 ppi reticulated polyether foam, which was then cut to a 13″×13″ sample size. The foam was framed in an extrusion vent panel frame along with galvanized steel wire mesh. The wire mesh was made of 0.047″ diameter wire and in a 4×4 mesh per inch pattern on each of the opposing sides of the foam. The framed materials were tested for shielding effectiveness using test method IEEE-299-1997 specification modified by utilizing a MIL-DTL-83528C test fixture (modified to fit the framed sample). For this framed EMI vent panel configuration, the test results revealed an average attenuation was 59.4 dB across a frequency range of 200 MHz to 18 GHz. Airflow testing (per ASTM F778 with a modified sample size diameter of 47 mm) revealed that the airflow through the specimen with this same foam and wire mesh on each side of the foam was 933 feet/minute at 0.200 inches of H₂O pressure. In comparison, the airflow through the foam alone was 1031 feet/minute at 0.200 inches of H₂O pressure. A sample of this same foam with wire mesh on each side of the foam was also tested for rigidity per ASTM D790 standard. The test standard was modified by testing one sample specimen, recording the force required to displace the specimen at specified displacement over a finite range over a span of 2.28 inches and depth of 0.894 inches. A force of 114.72 ounces/inch width was needed for a 0.25 inch displacement of a 1″×5″ sample of this foam and wire mesh combination. The force required for displacement of the foam alone from 0.00 to 0.65 inches was below the detection capability of the load cell of the testing apparatus.

In a second one of these additional embodiments tested for shielding effectiveness, airflow, and rigidity, the test specimen comprised ¼″ thick nickel copper plated 20 ppi reticulated polyurethane foam, which was cut to a 13″×13″ sample size. The foam was framed in an extrusion vent panel frame, along with copper wire mesh. The wire mesh was made of 0.028″ diameter wire and in an 8×8 mesh per inch pattern on each of the opposing sides of the foam. The framed materials were then tested for shielding effectiveness using test method IEEE-299-1997 specification modified by utilizing a MIL-DTL-83528C test fixture, which was modified to fit the framed sample. For this framed combination of foam and wire mesh, the average attenuation was 54.7 dB across a frequency range of 200 MHz to 18 GHz. A sample of the same foam and the same wire mesh on each side of the foam was also tested for airflow using test method ASTM F778 with a modified sample size diameter of 47 mm. The airflow through the material at 0.200 inches of H₂O pressure was 1227 feet/minute. In comparison, the airflow through the foam alone was 1669 feet/minute at 0.200 inches of H₂O pressure. A sample of the same foam and the same wire mesh on each side of the foam was tested for rigidity using the flexure test method ASTM D790. The test standard was modified by testing one sample specimen, and recording the force required to displace the specimen at specified displacement over a finite range over a span of 2.28 inches and depth of 0.894 inches. A force of 30.72 ounces/inch width was required to displace a 1″×5″ sample of the same foam and wire mesh combination a displacement of 0.25 inches. The force required for displacement of the foam alone from 0.00 to 0.65 inches was below the detection capability of the load cell of the testing apparatus.

In a third additional embodiment tested for shielding effectiveness, airflow, and rigidity, the test specimen included ¼″ thick nickel copper plated 6 ppi reticulated polyurethane foam. The foam was cut to a 13″×13″ sample size, and framed in an extrusion vent panel frame with aluminum wire mesh. The wire mesh was made of 0.023″ diameter wire and in a 12×12 mesh per inch pattern on each opposing side of the foam. The framed materials were then tested for shielding effectiveness using test method IEEE-299-1997 specification modified by utilizing a MIL-DTL-83528C test fixture, which was modified to fit the framed sample. For this framed combination of foam and wire mesh, the average attenuation was 50.0 dB across a frequency range of 200 MHz to 18 GHz. A sample of the same foam and the same wire mesh on each side of the foam was tested for airflow using test method ASTM F778 with a modified sample size diameter of 47 mm. The airflow through the material at 0.200 inches of H₂O pressure was 1276 feet/minute. The airflow through the foam alone was 1767 feet/minute at 0.200 inches of H₂O pressure. A sample of the same foam and the same wire mesh on each side of the foam was further tested for rigidity using the flexure test method ASTM D790. The test standard was modified by testing one sample specimen, and recording the force required to displace the specimen at specified displacement over a finite range over a span of 2.28 inches and depth of 0.894 inches. A force of 15.52 ounces/inch width was needed for a 0.25 inch displacement of a 1″×5″ sample of the same foam and wire mesh combination. The force required for displacement of the foam alone from 0.00 to 0.65 inches was below the detection capability of the load cell of the testing apparatus.

In a fourth additional embodiment tested for shielding effectiveness, airflow, and rigidity, the test specimen includes ¼″ thick tin copper plated 6 ppi reticulated polyurethane foam. The foam was cut to a 13″×13″ sample size, and then framed in an extrusion vent panel frame with stainless steel wire mesh. The wire mesh was made of 0.009″ diameter wire and in a 16×16 mesh per inch pattern on each of the opposing sides of the foam. The framed materials were then tested for shielding effectiveness using test method IEEE-299-1997 specification modified by utilizing a MIL-DTL-83528C test fixture, which was modified to fit the framed sample. For this framed combination of foam and wire mesh, the average attenuation was 50.1 dB across a frequency range of 200 MHz to 18 GHz. A sample of the same foam and the same wire mesh on each side of the foam was also tested for airflow using test method ASTM F778 with a modified sample size diameter of 47 mm. The airflow through the material at 0.200 inches of H₂O pressure was 933 feet/minute. The airflow through the foam alone was 1767 feet/minute at 0.200 inches of H₂O pressure. A sample of the same foam and the same wire mesh on each side of the foam was further tested for rigidity using the flexure test method ASTM D790. The test standard was modified by testing one sample specimen, and recording the force required to displace the specimen at specified displacement over a finite range over a span of 2.28 inches and depth of 0.894 inches. A force of 2.56 ounces/inch width was needed for a 0.25 inch displacement of a 1″×5″ sample of the same foam and wire mesh combination. The force required for displacement of the foam alone from 0.00 to 0.65 inches was below the detection capability of the load cell of the testing apparatus.

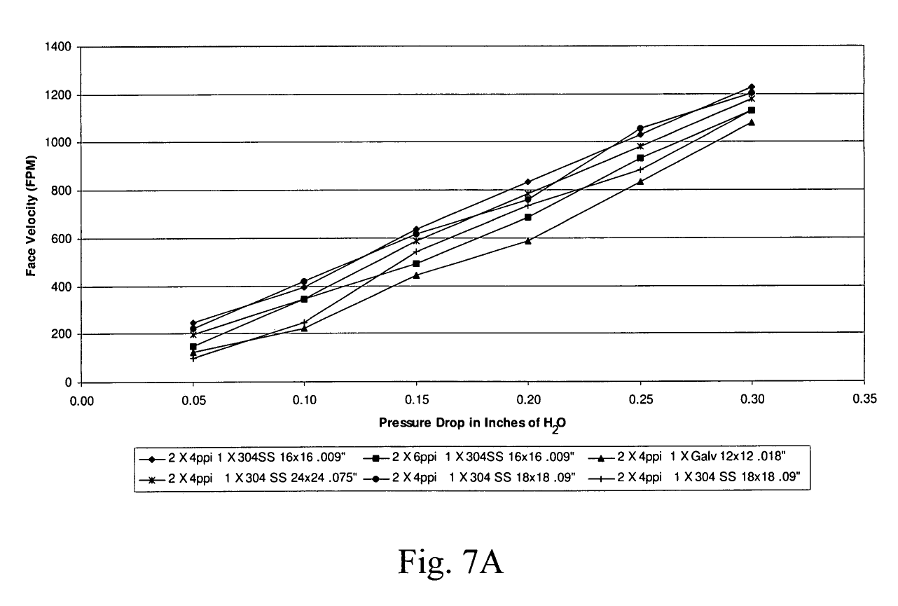

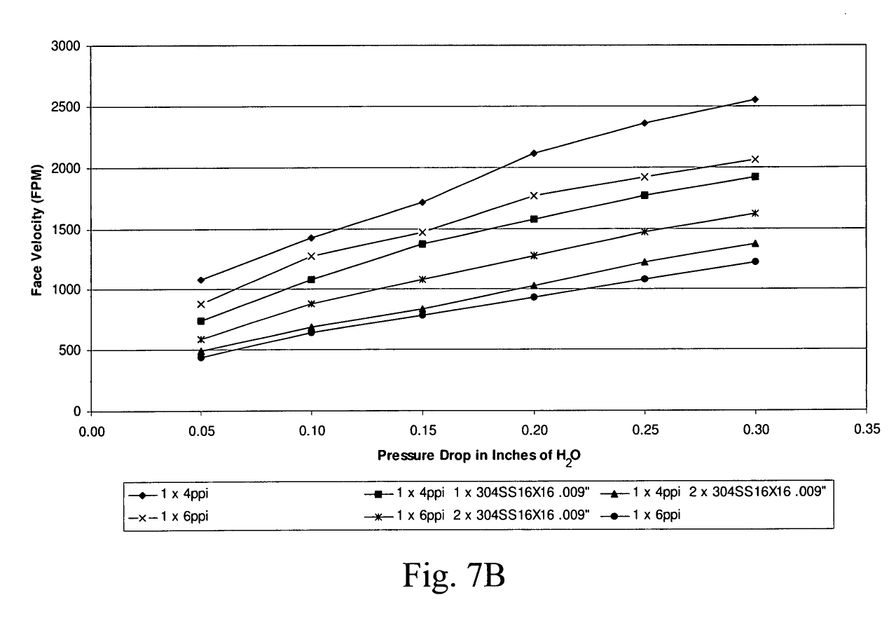

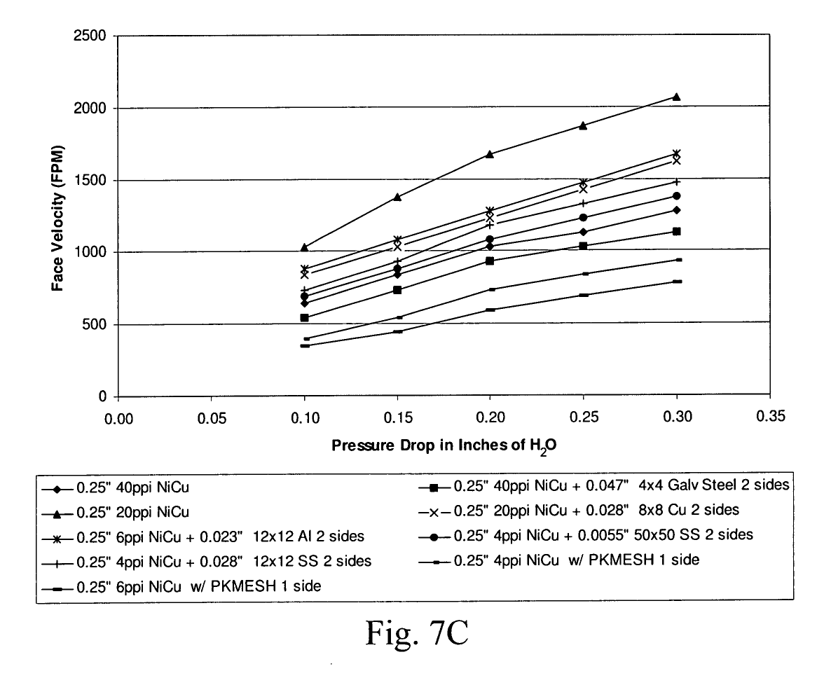

FIGS. 6A through 6C are tables summarizing data collected for various exemplary embodiments of EMI vent panels that were tested per ASTM F778 (Clear Air Permeability, 2001). FIGS. 7A through 7C are exemplary line graphs created from the data in FIGS. 6A through 6C, respectively, showing face velocity (in feet per minute) versus pressure drop (in inches of H₂O) for various exemplary embodiments of EMI vent panels.

The following is a description of the test specimens in the order that they are set forth in FIGS. 6A and 7A:
2 layers of nickel copper plated 4 ppi reticulated polyester foam (¼″ thickness each) and type 304 stainless steel wire mesh with 0.009″ diameter wire and 16×16 mesh per inch pattern on only one side of the foam;
2 layers of nickel copper plated 6 ppi reticulated polyester foam (¼″ thickness each) and type 304 stainless steel wire mesh with 0.009″ diameter wire and 16×16 mesh per inch pattern on only one side of the foam;
2 layers of nickel copper plated 4 ppi reticulated polyester foam (¼″ thickness each) and galvanized steel wire mesh with 0.018″ diameter wire and 12×12 mesh per inch pattern on only one side of the foam;
2 layers of nickel copper plated 4 ppi reticulated polyester foam (¼″ thickness each) and type 304 stainless steel wire mesh with 0.055″ diameter wire and 50×50 mesh per inch pattern on only one side of the foam;
2 layers of nickel copper plated 4 ppi reticulated polyester foam (¼″ thickness each) and type 304 stainless steel wire mesh with 0.075″ diameter wire and 24×24 mesh per inch pattern on only one side of the foam; and

2 layers of nickel copper plated 4 ppi reticulated polyester foam (¼″ thickness each) and type 304 stainless steel wire mesh with 0.009″ diameter wire and 18×18 mesh per inch pattern on only one side of the foam.

The test conditions under which the results shown in FIGS. 6A and 7A were obtained included a temperature of 71 degrees Fahrenheit, relative humidity of 45%, barometric pressure of 733 mm Hg, and with samples being flat sheet media cut to 47 mm test area 0.011 feet squared.

The following is a description of the test specimens in the order that they are set forth in FIGS. 6B and 7B:
nickel copper plated 4 ppi reticulated polyester foam (¼″ thickness) without any wire mesh;
nickel copper plated 4 ppi reticulated polyester foam (¼″ thickness) and type 304 stainless steel wire mesh with 0.009″ diameter wire and 16×16 mesh per inch pattern on only one side of the foam;
nickel copper plated 4 ppi reticulated polyester foam (¼″ thickness) and type 304 stainless steel wire mesh with 0.009″ diameter wire and 16×16 mesh per inch pattern on both sides of the foam;
nickel copper plated 6 ppi reticulated polyester foam (¼″ thickness) without any wire mesh;
nickel copper plated 6 ppi reticulated polyester foam (¼″ thickness) and type 304 stainless steel wire mesh with 0.009″ diameter wire and 16×16 mesh per inch pattern on only one side of the foam; and
nickel copper plated 6 ppi reticulated polyester foam (¼″ thickness) and type 304 stainless steel wire mesh with 0.009″ diameter wire and 16×16 mesh per inch pattern on both sides of the foam.

The test conditions under which the results shown in FIGS. 6B and 7B were obtained included a temperature of 72 degrees Fahrenheit, relative humidity of 48%, barometric pressure of 736 mm Hg, and with samples being flat sheet media cut to 47 mm test area 0.011 feet squared.

The following is a description of the test specimens in the order that they are set forth in FIGS. 6C and 7C:
nickel copper plated 40 ppi reticulated polyether foam (¼″ thickness) without any wire mesh;
nickel copper plated 40 ppi reticulated polyether foam (¼″ thickness) and type 304 stainless steel wire mesh with 0.047″ diameter wire and 4×4 mesh per inch pattern on both sides of the foam;
nickel copper plated 20 ppi reticulated polyether foam (¼″ thickness) without any wire mesh;
nickel copper plated 20 ppi reticulated polyether foam (¼″ thickness) and copper wire mesh with 0.028″ diameter wire and 8×8 mesh per inch pattern on both sides of the foam;
nickel copper plated 6 ppi reticulated polyester foam (¼″ thickness) and aluminum wire mesh with 0.023″ diameter wire and 12×12 mesh per inch pattern on both sides of the foam;
nickel copper plated 4 ppi reticulated polyester foam (¼″ thickness) and type 304 stainless steel wire mesh with 0.055″ diameter wire and 50×50 mesh per inch pattern on both sides of the foam;
nickel copper plated 4 ppi reticulated polyester foam (¼″ thickness) and type 304 stainless steel wire mesh with 0.028″ diameter wire and 12×12 mesh per inch pattern on both sides of the foam;
nickel copper plated 4 ppi reticulated polyester foam (¼″ thickness) and polyester knit mesh (PKMesh) on one side of the foam; and
nickel copper plated 6 ppi reticulated polyester foam (¼″ thickness) and polyester knit mesh (PKMesh) on one side of the foam.
   The test conditions under which the results shown in FIGS. 6C and 7C were obtained included a temperature of 72 degrees Fahrenheit, relative humidity of 51%, barometric pressure of 706 mm Hg, and with samples being flat sheet media cut to 47 mm test area 0.011 feet squared.

FIGS. 8A through 8I are exemplary line graphs of flexure force showing displacement versus force required for causing that displacement for various test specimens having a width of one inch and length of five inches. These rigidity test results were obtained using a modified ASTM D790 standard, during which each specimen was tested to record the force required to displace that specimen at specified displacements from 0.00 to 0.65 inches across a span of 2.28 inches and depth of 0.894 inches.

The following is a description of the test specimens in the order that they are set forth in FIG. 8A:
2 layers of nickel copper plated 6 ppi reticulated polyester foam (¼″ thickness) without any wire mesh;
2 layers of nickel copper plated 6 ppi reticulated polyester foam (¼″ thickness each) and type 304 stainless steel wire mesh with 0.009″ diameter wire and 16×16 mesh per inch pattern on only one side of the foam;
2 layers of nickel copper plated 6 ppi reticulated polyester foam (¼″ thickness each) and galvanized steel wire mesh with 0.018″ diameter wire and 12×12 mesh per inch pattern on only one side of the foam; and
2 layers of nickel copper plated 6 ppi reticulated polyester foam (¼″ thickness each) and type 304 stainless steel wire mesh with 0.055″ diameter wire and 50×50 mesh per inch pattern on only one side of the foam;
2 layers of nickel copper plated 6 ppi reticulated polyester foam (¼″ thickness each) and type 304 stainless steel wire mesh with 0.075″ diameter wire and 24×24 mesh per inch pattern on only one side of the foam.

The following is a description of the test specimens in the order that they are set forth in FIG. 8B:
nickel copper plated 4 ppi reticulated polyester foam (¼″ thickness) without any wire mesh (this is listed in figure's legend, but flexure forces were below detection capability of the load cell of the testing apparatus);
nickel copper plated 4 ppi reticulated polyester foam (¼″ thickness) and type 304 stainless steel wire mesh with 0.009″ diameter wire and 16×16 mesh per inch pattern on only one side of the foam;
nickel copper plated 4 ppi reticulated polyester foam (¼″ thickness) and type 304 stainless steel wire mesh with 0.055″ diameter wire and 50×50 mesh per inch pattern on both sides of the foam; and
nickel copper plated 4 ppi reticulated polyester foam (¼″ thickness) and type 304 stainless steel wire mesh with 0.028″ diameter wire and 12×12 mesh per inch pattern on only one side of the foam.

The following is a description of the test specimens in the order that they are set forth in FIG. 8C:
nickel copper plated 6 ppi reticulated polyester foam (¼″ thickness) without any wire mesh (this is listed in figure's legend, but flexure forces were below detection capability of the load cell of the testing apparatus);
nickel copper plated 6 ppi reticulated polyester foam (¼″ thickness) and aluminum wire mesh with 0.023″ diameter wire and 12×12 mesh per inch pattern on only one side of the foam; and
nickel copper plated 6 ppi reticulated polyester foam (¼″ thickness) and type 304 stainless steel wire mesh with 0.009″ diameter wire and 16×16 mesh per inch pattern on both sides of the foam.

The following is a description of the test specimens in the order that they are set forth in FIG. 8D:
nickel copper plated 20 ppi reticulated polyether foam (¼″ thickness) without any wire mesh (this is listed in figure's legend, but flexure forces were below detection capability of the load cell of the testing apparatus); and
nickel copper plated 20 ppi reticulated polyester foam (¼″ thickness) and copper wire mesh with 0.028″ diameter wire and 8×8 mesh per inch pattern on only one side of the foam.

The following is a description of the test specimens in the order that they are set forth in FIG. 8E:
nickel copper plated 40 ppi reticulated polyether foam (¼″ thickness) without any wire mesh (this is listed in figure's legend, but flexure forces were below detection capability of the load cell of the testing apparatus); and
nickel copper plated 40 ppi reticulated polyether foam (¼″ thickness) and galvanized steel wire mesh with 0.047″ diameter wire and 4×4 mesh per inch pattern on both sides of the foam.

The following is a description of the test specimens in the order that they are set forth in FIG. 8F:
nickel copper plated 4 ppi reticulated polyester foam (¼″ thickness) without any wire mesh (this is listed in figure's legend, but flexure forces were below detection capability of the load cell of the testing apparatus);
nickel copper plated 4 ppi reticulated polyester foam (¼″ thickness) and type 304 stainless steel wire mesh with 0.009″ diameter wire and 16×16 mesh per inch pattern on both sides of the foam;
nickel copper plated 4 ppi reticulated polyester foam (¼″ thickness) and type 304 stainless steel wire mesh with 0.055″ diameter wire and 50×50 mesh per inch pattern on both sides of the foam; and
nickel copper plated 4 ppi reticulated polyester foam (¼″ thickness) and type 304 stainless steel wire mesh with 0.028″ diameter wire and 12×12 mesh per inch pattern on both sides of the foam.

The following is a description of the test specimens in the order that they are set forth in FIG. 8G:
nickel copper plated 6 ppi reticulated polyester foam (¼″ thickness) without any wire mesh (this is listed in figure's legend, but flexure forces were below detection capability of the load cell of the testing apparatus);
nickel copper plated 6 ppi reticulated polyester foam (¼″ thickness) and aluminum wire mesh with 0.023″ diameter wire and 12×12 mesh per inch pattern on only one side of the foam; and nickel copper plated 6 ppi reticulated polyester foam (¼″ thickness) and type 304 stainless steel wire mesh with 0.009″ diameter wire and 16×16 mesh per inch pattern on both sides of the foam.

The following is a description of the test specimens in the order that they are set forth in FIG. 8H:
nickel copper plated 20 ppi reticulated polyether foam (¼″ thickness) without any wire mesh (this is listed in figure's legend, but flexure forces were below detection capability of the load cell of the testing apparatus); and
nickel copper plated 20 ppi reticulated polyester foam (¼″ thickness) and copper wire mesh with 0.028″ diameter wire and 8×8 mesh per inch pattern on both sides of the foam.

The following is a description of the test specimens in the order that they are set forth in FIG. 8I:
nickel copper plated 40 ppi reticulated polyether foam (¼″ thickness) without any wire mesh (this is listed in figure's legend, but flexure forces were below detection capability of the load cell of the testing apparatus); and
nickel copper plated 40 ppi reticulated polyester foam (¼″ thickness) and galvanized steel wire mesh with 0.047″ diameter wire and 4×4 mesh per inch pattern on both sides of the foam.

Various aspects of this disclosure can be used in a wide range of installations and applications for providing EMI shielding, non-EMI shielding applications, thermal cooling, air filtration, gasketing, die cut sections, vent panels, air filtration panels, laminates, combinations thereof, etc. Accordingly, the specific references to vent panel or air filtration panel should not be construed as limiting the scope of the disclosure to only one specific form/type of vent panel or air filtration panel. In addition, aspects of the disclosure can also be employed in non-EMI applications, such as water filters, chemical filters, and medical applications.

Further, the particular methods of manufacture and geometries disclosed herein are exemplary in nature and are not to be considered limiting. The steps, processes, and operations described herein are not to be construed as necessarily requiring their performance in the particular order discussed or illustrated, unless specifically identified as an order of performance. It is also to be understood that additional or alternative steps may be employed. In addition, any one or more aspects of the disclosure may be implemented individually or in any combination with any one or more of the other aspects of the disclosure.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features of the present disclosure and exemplary embodiments, the articles “a”, “an”, “the”, and “said” are intended to mean that there are one or more of such elements or features. The terms “comprising”, “including”, and “having” are intended to be inclusive and mean that there may be additional elements or features other than those specifically noted.

The description of the disclosure is merely exemplary in nature and, thus, variations that do not depart from the gist of the disclosure are intended to be within the scope of the disclosure. Such variations are not to be regarded as a departure from the spirit and scope of the disclosure.

What is claimed is:

1. An electromagnetic interference (EMI) shielding vent panel comprising an electrically-conductive polymeric foam having first and second sides and a plurality of pores in a substantially nonuniform configuration, and an electrically-conductive wire mesh adjacent at least a portion of at least one of the first and second sides of the electrically-conductive polymeric foam, for increasing shielding effectiveness of the vent panel, as compared to shielding effectiveness of the electrically-conductive polymeric foam alone.

2. The vent panel of claim 1, wherein the vent panel has a shielding effectiveness of greater than about thirty decibels across a frequency range from about two hundred megahertz to about eighteen gigahertz.

3. The vent panel of claim 1, wherein the electrically-conductive wire mesh is configured to reinforce the electrically-conductive polymeric foam, thereby increasing rigidity of the vent panel.

4. The vent panel of claim 1, wherein the vent panel allows an airflow of at least about 800 feet/minute at 0.200 inches of H₂O pressure drop.

5. The vent panel of claim 1, wherein at least some of the pores of the electrically-conductive porous substrate have a non-honeycombed configuration.

6. The vent panel of claim 1, wherein the electrically-conductive polymeric foam has a pore density about equal to or less than about forty pores per inch.

7. The vent panel of claim 1, wherein the electrically-conductive polymeric foam comprises open-celled polymeric foam having a pore density equal to or less than about forty pores per inch.

8. The vent panel of claim 1, wherein the electrically-conductive polymeric foam comprises one or more of ester-based polyurethane, ether-based polyurethane, polyvinyl, polystyrene, silicone, polyethylene, polypropylene, polybutadiene, cellulose sponge, or a combination thereof.

9. The vent panel of claim 1, wherein the electrically-conductive polymeric foam includes open-celled polymeric foam provided with at least one metallic layer.

10. The vent panel of claim 9, wherein the at least one metallic layer comprises one or more of copper, nickel, palladium, platinum, silver, tin, gold, or an alloy thereof.

11. The vent panel of claim 1, wherein the electrically-conductive wire mesh has a wire diameter equal to or greater than about 0.0037 inches.

12. The vent panel of claim 1, wherein the electrically-conductive wire mesh has about 120×120 meshes per linear inch or less.

13. The vent panel of claim 1, wherein the electrically-conductive wire mesh comprises one or more of copper, nickel, aluminum, stainless steel, galvanized steel, or an alloy thereof.

14. The vent panel of claim 1, wherein the electrically-conductive wire mesh is disposed alongside both of the first and second sides of the electrically-conductive polymeric foam.

15. The vent panel of claim 1, wherein the electrically-conductive polymeric foam includes internal interstices impregnated with an effective amount of flame retardant to provide the electrically-conductive polymeric foam with a UL94 flame rating of V0.

16. An electromagnetic interference (EMI) shield comprising a metallized porous substrate having first and second sides and a plurality of pores in a substantially nonuniform configuration with a pore density equal to or less than about forty pores per inch, and an electrically-conductive wire mesh adjacent at least a portion of at least one of the first and second sides of the metallized porous substrate, the electrically-conductive wire mesh having about 120×120 meshes per linear inch or less, and a wire diameter equal to or greater than about 0.0037 inches.

17. The shield of claim 16, wherein the electrically-conductive wire mesh is configured to increase shielding effectiveness of the shield as compared to shielding effectiveness of the metallized porous substrate alone.

18. The shield of claim 16, wherein the electrically-conductive wire mesh is configured to increase rigidity of the shield as compared to the rigidity of the metallized porous substrate alone.

19. The shield of claim 16, wherein the shield has a shielding effectiveness of greater than about thirty decibels across a frequency range from about two hundred megahertz to about eighteen gigahertz.

20. The shield of claim 16, wherein the shield allows an airflow of at least about 800 feet/minute at 0.200 inches of H₂O pressure drop.

21. The shield of claim 16, wherein at least some of the pores of the electrically-conductive porous substrate have a non-honeycombed configuration.

22. The shield of claim 16, wherein the electrically-conductive porous substrate comprises open-celled polymeric foam having a pore density of equal to or less than about forty pores per inch, and provided with at least one metallic layer of one or more of copper, nickel, palladium, platinum, silver, tin, gold, or an alloy thereof.

23. The shield of claim 22, wherein the electrically-conductive wire mesh comprises one or more of copper, nickel, aluminum, stainless steel, galvanized steel, or an alloy thereof.

24. The shield of claim 16, wherein the electrically-conductive wire mesh is disposed alongside both of the first and second sides of the electrically-conductive porous substrate.

25. An electromagnetic interference (EMI) shielding vent panel comprising:
an electrically-conductive polymeric foam having first and second generally opposing sides and a plurality of pores at least some of which have a non-honeycombed configuration, the electrically-conductive polymeric foam having a pore density equal to or less than about forty pores per inch;
an electrically-conductive wire mesh adjacent at least a portion of at least one of the first and second sides of the electrically-conductive polymeric foam for increasing shielding effectiveness, the electrically-conductive wire mesh having a wire diameter equal to or greater than about 0.0037 inches, the electrically-conductive wire mesh having about 120×120 meshes per linear inch or less;
wherein the vent panel has a shielding effectiveness of greater than about thirty decibels across a frequency range from about two hundred megahertz to about eighteen gigahertz; and
wherein the vent panel allows an airflow of at least about 800 feet/minute at 0.200 inches of H₂O pressure drop.

26. The vent panel of claim 25, wherein the electrically-conductive wire mesh is disposed alongside both of the first and second sides of the electrically-conductive polymeric foam.
